(19) United States
(12) Patent Application Publication
(10) Pub. No.: US 2025/0246418 A1
(43) Pub. Date: Jul. 31, 2025

(54) SENSOR IN CHAMBER INSERT RING ASSEMBLY

(71) Applicant: Tokyo Electron Limited, Tokyo (JP)

(72) Inventors: Joel Blakeney, Austin, TX (US); Zhiying Chen, Austin, TX (US); Megan Carruth, Austin, TX (US)

(21) Appl. No.: 18/425,323

(22) Filed: Jan. 29, 2024

(51) Int. Cl. H01J 37/32

(52) U.S. Cl. CPC H01J 37/32972; H01J 37/32642; H01J 37/3299; H01J 37/32963; H01J 2237/3321; H01J 2237/3341

(57) ABSTRACT

According to an embodiment, a plasma chamber having a substrate holder, a ring assembly, and a fiber optic cable is proposed. The substrate holder having a top surface and a bottom surface. The top surface of the substrate holder is configured to hold a substrate for plasma processing. The ring assembly includes a focus ring horizontally surrounding the substrate. The focus ring includes a cavity arranged in a vertical direction from the bottom surface of the substrate holder to the top surface of the substrate holder. The fiber optic cable is fed through the cavity. The fiber optic cable having an endpoint configured to collect light emitted by plasma to determine its species density as well as atomic or ionic composition.

### TECHNICAL FIELD

The present disclosure generally relates to a plasma processing system and, in particular embodiments, to an arrangement of an optical emission spectroscopy sensor for a plasma chamber.

### BACKGROUND

An Optical Emission Spectroscopy (OES) sensor is used to analyze and monitor systems in various scientific and industrial applications. Its function is based on the principle of analyzing the light emitted (e.g., in the visible and ultraviolet range) by an excited element to determine its atomic or ionic composition. Generally, the OES sensor includes a light collection mechanism to collect optical signals to be decoded into useful data. It can provide real-time, in-situ, and highly sensitive monitoring data, indispensable in several demanding fields such as semiconductor manufacturing.

In semiconductor manufacturing, the OES sensor can be incorporated into a plasma chamber as a diagnostic tool for plasma processes. Plasma processing is a critical step in semiconductor fabrication, involving operations like etching, deposition, and surface modification, which leverage the high reactivity of plasma species. The OES sensor can aid in analyzing and controlling the plasma parameters. It can collect the optical emission from the processing plasma, identify the specific wavelengths corresponding to different elements or compounds, and measure their intensity. This information can, for example, denote the presence and concentration of various species in the plasma, the degree of ionization, and other plasma properties.

Further, the data acquired by the OES sensor can be exploited as a feedback tool to regulate the plasma process. It can assist in maintaining uniform conditions across the plasma chamber, optimizing the process parameters, and achieving the desired material characteristics on the semiconductor wafer. The OES sensor can also detect process deviations or anomalies, helping to ensure the reliability and efficiency of the semiconductor manufacturing operations. Hence, integrating an OES sensor into the plasma chamber is significant for real-time process control and quality assurance in semiconductor production.

### SUMMARY

Technical advantages are generally achieved by embodiments of this disclosure, which describe an arrangement of an optical emission spectroscopy sensor for a plasma chamber.

A first aspect relates to a plasma chamber. The plasma chamber includes a substrate holder, a ring assembly, and a fiber optic cable. The substrate holder having a top surface and a bottom surface. The top surface of the substrate holder is configured to hold a substrate for plasma processing. The ring assembly includes a focus ring horizontally surrounding the substrate. The focus ring includes a cavity arranged in a vertical direction from the bottom surface of the substrate holder to the top surface of the substrate holder. The fiber optic cable is fed through the cavity. The fiber optic cable having an endpoint configured to collect light emitted by plasma to determine its atomic or ionic composition.

A second aspect relates to a plasma chamber. The plasma chamber includes a substrate holder, a ring assembly, and a fiber optic cable. The substrate holder having a top surface and a bottom surface. The top surface of the substrate holder configured to hold a substrate for plasma processing. The ring assembly having a focus ring horizontally surrounding the substrate and a shadow ring horizontally surrounding the focus ring. The shadow ring having a cavity. The fiber optic cable being fed through the cavity. The fiber optic cable having an endpoint configured to collect light emitted by plasma to determine its atomic or ionic composition.

A third aspect relates to a ring structure for a plasma processing system. The ring structure including a focus ring and a shadow ring. The focus ring horizontally surrounding a substrate. The focus ring having a first cavity. A first fiber optic cable is fed through the first cavity to a first surface of the focus ring. The first fiber optic cable having an endpoint configured to collect light emitted by plasma at a first volume within a plasma chamber of the plasma processing system to determine its atomic or ionic composition. The shadow ring horizontally surrounds the focus ring. The shadow ring having a second cavity. A second fiber optic cable is fed through the second cavity to a first surface of the shadow ring. The second fiber optic cable having an endpoint configured to collect light emitted by plasma at a second volume within the plasma chamber to determine its atomic or ionic composition.

Embodiments can be implemented in hardware, software, or any combination thereof.

### BRIEF DESCRIPTION OF THE DRAWINGS

For a more complete understanding of the present disclosure and the advantages thereof, reference is now made to the following descriptions taken in conjunction with the accompanying drawings, in which:

FIG. 1 is a diagram of an embodiment plasma processing system;

FIG. 2 is a flow chart of an embodiment method for operating the plasma processing system based on a feedback mechanism;

FIG. 3 is a block diagram of sensor and control system for a plasma processing system;

FIG. 4A is a cross-sectional view of an embodiment ring assembly; and

FIG. 4B is a top view of the ring assembly.

### DETAILED DESCRIPTION OF ILLUSTRATIVE EMBODIMENTS

This disclosure provides many applicable inventive concepts that can be embodied in a wide variety of specific contexts. The particular embodiments are merely illustrative of specific configurations and do not limit the scope of the claimed embodiments. Features from different embodiments may be combined to form further embodiments unless noted otherwise. Various embodiments are illustrated in the accompanying drawing figures, where identical components and elements are identified by the same reference number, and repetitive descriptions are omitted for brevity.

Variations or modifications described in one of the embodiments may also apply to others. Further, various changes, substitutions, and alterations can be made herein without departing from the spirit and scope of this disclosure as defined by the appended claims.

While the inventive aspects are described primarily in the context of an optical emission spectroscopy (OES) sensor for a plasma processing system, it should also be appreciated that these inventive aspects may also apply to other commercial or consumer-based products. In particular, aspects of this disclosure may similarly apply to the arrangement of other types of sensors in a plasma processing system that benefit from remote sensing, such as the placement of an optical temperature sensor. Further, the inventive aspects may similarly apply to fields outside the semiconductor industry. Plasma can treat and modify surface properties through functional group addition. For example, to treat surfaces for paint deposits, plasma can convert hydrophobic surfaces to hydrophilic surfaces. Moreover, the inventive aspects are not limited to plasma.

It should be noted that would just emphasize that optical emission spectroscopy provides density to the plasma species in addition to what plasma composition is happening during etch or deposition. In some instances, the composition can be known based on previous studies.

Despite the advancements in the semiconductor manufacturing industry and the critical role played by plasma processing, a notable limitation that persists today is the lack of sensors that can provide real-time, in-situ information about plasma parameters for advanced equipment control algorithms. There's a growing technology gap stemming from the increasing complexity of plasma processes and the emerging demands for higher precision and efficiency in semiconductor markets.

Traditional process control systems in semiconductor equipment are based on fixed recipes with pre-set parameters. Consequently, they may not aptly respond to real-time variations in the plasma environment. The closed-loop control algorithms in these systems are deprived of real-time, relevant, and direct information about the plasma characteristics. As a result, these algorithms may be unable to make dynamic adjustments, leading to inefficient plasma processing and sub-optimal semiconductor device properties.

Sensors continuously monitoring the in-situ plasma conditions can facilitate improved feedback for advanced equipment control algorithms. Such sensors can aid in detecting minute shifts in the plasma parameters in real-time, thereby providing a proportionate response for near-immediate corrective actions. This, in turn, paves the way for enhanced processing stability, reduced process variability, and improved manufacturing yield.

Conventionally, the Optical Emission Spectroscopy (OES) sensor is placed at a side window of the side wall of a plasma chamber. Disadvantageously, the conventional arrangement of the OES sensor is limited to providing an average measurement of the plasma in the chamber.

Embodiments of this disclosure provide an arrangement of OES sensors that transform the conventional methods for monitoring and control in plasma processing. In embodiments, the OES sensor is embedded in a ring assembly (i.e., focus ring, shadow ring, or both) of a plasma chamber, offering the potential for in-situ plasma monitoring at the wafer surface. Advantageously, the proposed arrangement of the OES sensor allows for improved controllability of the collected light by directing the collection to specific volumes across the surface of the substrate from, for example, the center to the edge of the substrate.

The focus ring in a plasma chamber is a boundary structure framing the wafer. It also contributes to confining and shaping the plasma within the chamber. The shadow ring frames the focus ring. By incorporating the OES sensor into the focus ring, the shadow ring, or both, the emitted light from the plasma close to the wafer surface can be captured more directly and accurately. This setup caters to significantly efficient and precise plasma diagnostics, overcoming any constraints posed by conventional sensing methods.

In embodiments, integrating an OES sensor into the chamber focus ring essentially transforms the sensor's location to be almost co-planar with the wafer surface. In other words, the sensor can capture valuable optical emission data virtually from the immediate plasma environment of the wafer. This in-situ capability allows the sensor to detect even the slightest changes in plasma characteristics as the wafer processing progresses.

Furthermore, this OES sensor integrated into the focus ring can provide in-depth and real-time data about the plasma. This includes diverse plasma parameters such as the concentration of various chemical species, ionization level, plasma temperature, and more. Thus, it allows for tracking the dynamic fluctuations of plasma, diagnosing processing conditions, and delivering immediate and pertinent feedback for process control. These and other details are described in further detail below.

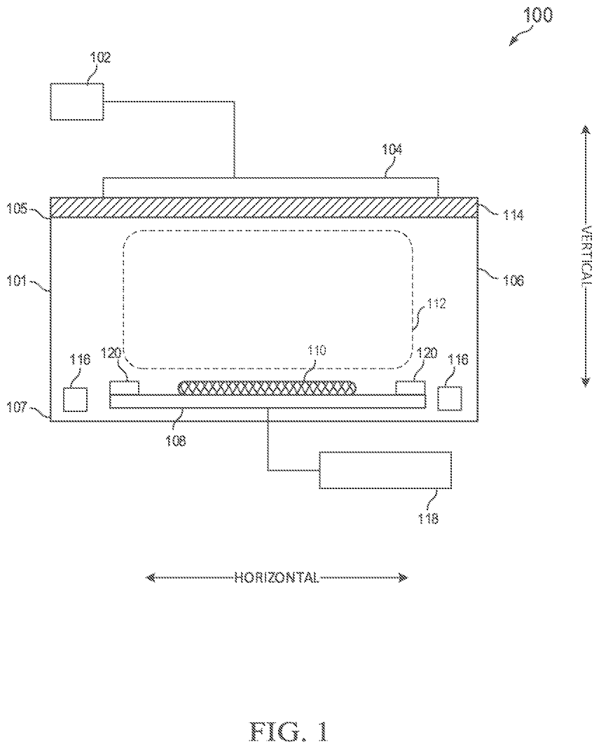

FIG. 1 illustrates a diagram of an embodiment plasma processing system 100. Plasma processing system 100 includes an RF source 102, a radiating antenna 104, a plasma chamber 106, and, optionally, a dielectric plate 114, which may (or may not) be arranged as shown in FIG. 1. Further, plasma processing system 100 may include additional components not depicted in FIG. 1, such as a matching network between the RF source 102 and the radiating antenna 104. The plasma processing system 100, in embodiments, may be housed within an enclosure, which may be a Faraday cage or solid.

RF source 102 provides forward RF waves to the radiating antenna 104. The forward RF waves travel through the radiating antenna 104 and are transmitted (i.e., radiated) towards plasma chamber 106.

The plasma chamber 106 may include sidewalls 101, a base 107, and a top cover 105, which may be made of a conductive material, for example, stainless steel or aluminum coated with a film, such as yttria (e.g., YxOy or YxOyFz, etc.), or a film consistent with the process (e.g., carbon, silicon, etc.), or as known to a person of ordinary skill in the art. In embodiments, plasma chamber 106 is cylindrical with a base 107 and a top cover 105 that are circular.

The plasma chamber 106 includes a substrate holder 108 (i.e., chuck). As shown, substrate 110 is placed on substrate holder 108, positioned at the base 107 of the plasma chamber 106, to be processed. The substrate holder 108 securely holds and electrostatically clamps the substrate 110 during processing.

The plasma chamber 106 also includes a focus ring 120 (in the shape of a ring surrounding the substrate 110). The focus ring 120 may advantageously maintain and extend the uniformity of a plasma 112 to achieve process consistency at the edge of the substrate 110. In various embodiments, the focus ring 120 may have a width of a few centimeters. In various embodiments, there may be a gap for mechanical clearance between the circumference of the substrate 110 and the focus ring 120. The gap may be hundreds of microns to a few millimeters in certain embodiments. The focus ring 120 is made of a dielectric material with a desired dielectric constant in various embodiments. In certain embodiments, the focus ring 120 is made of silicon. Some examples of silicon-based focus rings may comprise silicon, silicon oxide, doped silicon (e.g., boron-doped, nitrogen-doped, and phosphorous-doped), or silicon carbide. Alternatively, in some embodiments, the focus ring 120 is made of a carbon-based material. In one or more embodiments, the focus ring 120 is made of a metal oxide, such as aluminum oxide or zirconium oxide.

Optionally, plasma chamber 106 may include a bias power supply 118 coupled to the substrate holder 108 and the focus ring 120. Applying a bias to the focus ring 120 may improve the uniformity of the plasma 112 in the plasma chamber 106. In embodiments, a temperature controller (not shown) may be used to control the temperature of the focus ring 120.

Optionally, plasma chamber 106 may include one or more pump outlets 116 to remove by-products from plasma chamber 106 through selective control of gas flow rates within. In embodiments, pump outlets 116 are placed near (e.g., below/around the perimeter of) substrate holder 108 and substrate 110. In embodiments, plasma chamber 106 may include additional substrate holders (not shown). In embodiments, the placement of the substrate holder 108 may differ from that shown in FIG. 1. Thus, the quantity and position of the substrate holder 108 are non-limiting.

In embodiments, radiating antenna 104 is separated from the top cover 105 of the plasma chamber 106 by the dielectric plate 114 (i.e., a dielectric window), typically made of a dielectric material such as quartz. Dielectric plate 114 separates the low-pressure environment within the plasma chamber 106 from the external atmosphere. It should be appreciated that radiating antenna 104 can be placed directly adjacent to the top cover 105 of the plasma chamber 106, or radiating antenna 104 can be separated from plasma chamber 106 by air. In embodiments, the dielectric plate 114 is selected to minimize reflections of the RF wave from the plasma chamber 106. In other embodiments, the radiating antenna 104 is embedded within the dielectric plate 114.

In an embodiment, the radiating antenna 104 couples RF power from RF source 102 to the plasma chamber 106 to treat substrate 110. In particular, radiating antenna 104 radiates an electromagnetic wave in response to being fed the forward RF waves from the RF source 102. The radiated electromagnetic wave penetrates from the atmospheric side (i.e., radiating antenna 104 side) of the dielectric plate 114 into plasma chamber 106. The radiated electromagnetic wave generates an electromagnetic field within the plasma chamber 106. The generated electromagnetic field ignites and sustains plasma 112 by transferring energy to free electrons within the plasma chamber 106. The plasma 112 can be used to, for example, selectively etch or deposit material on substrate 110.

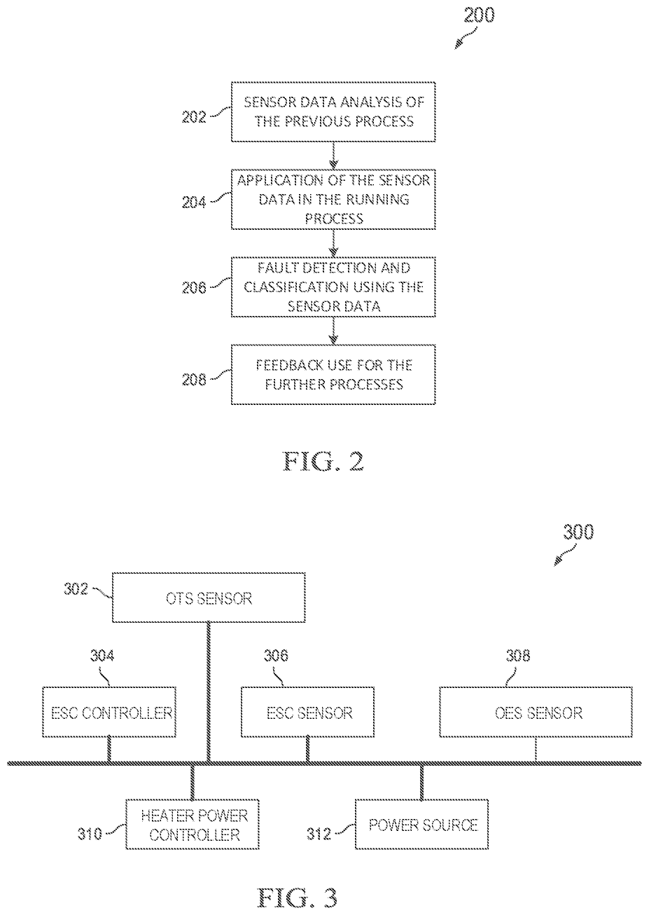

FIG. 2 illustrates a flow chart of an embodiment method 200 for operating the plasma processing system 100 based on a feedback mechanism. The array of demands associated with plasma technology (e.g., sub-10 nm) is multifaceted, including understanding plasma chemistry during plasma processing, assisting in developing prototype processes and contributing to fabricating advanced process control algorithms. Utilizing non-invasive in-situ plasma sensors is beneficial for effectively responding to these diverse challenges.

Metrology refers to the measurement and data analysis of system variables such as plasma density, temperature, and other constituents. Metrology from sensors in the plasma processing system 100 interacts and collects data in real-time during the plasma process, which includes the gathering of parameters like ion energy, particle flux, gas flow rate, RF power, and chamber pressure. This collected data aids in understanding the behavior and the state of the plasma 112 within the plasma chamber 106.

Advanced Process Control (APC) in the plasma chamber 106 leverages this metrology data in many ways. It uses these real-time measurements to adjust and optimize the processing conditions dynamically, thus ensuring the desired output parameters are maintained despite the inherent variability of the process. This controlled feedback loop increases process stability, improves product yield, and reduces manufacturing costs.

Moreover, APC can use the collected metrology data to identify any anomalies or drift in the parameters, allowing for predictive maintenance and quick mitigation of any issues before significant impacts on production occur. APC algorithms can also analyze this data for process optimization, improving reliability, repeatability, and overall equipment efficiency within the plasma chamber 106.

At step 202, the previous process in a plasma processing sequence is measured and analyzed using a variety of integrated sensors housed internally within and externally to the plasma chamber 106. These sensors, whether optical, temperature, pressure, flow, current, or voltage sensors or a combination thereof, monitor and gather data specific to the system's functioning. This could include emitted light, pressure levels, reaction rates, and chemical concentrations. The sensors can provide a detailed reading of the machinery's functioning and the process's performance, empowering operators with reliable, real-time data.

At step 204, the data generated by these sensors is used to examine the present state of the plasma processing system 100 and plays a critical role in its current working process. This data guides the operating controls, ensuring optimum performance and results. The current process relies on this sensor data for meticulous control, enabling the plasma processing system 100 to adjust and adapt to variant plasma conditions.

At step 206, the sensor data from the current process is also utilized to facilitate fault detection and classification (FDC). Potential faults, breaches, and system errors in the plasma processing system 100 can be quickly identified by monitoring and comparing current and historical data. The complex patterns and correlations in the data assist in classifying the faults and abnormalities, aiding in their prompt remediation.

At step 208, the feedback received from this fault detection and classification (FDC) process can be used for future process adjustments. The system learns from these mishaps, utilizing the feedback to enhance the next process. This learning curve allows constant improvements to the plasma processing system 100 over time, perfecting itself based on past experiences.

FIG. 3 illustrates a block diagram of sensor and control system 300 for a plasma processing system, such as the plasma processing system 100 in FIG. 1. As shown, the sensor and control system 300 includes an optical temperature sensor (OTS) 302, an electrostatic chuck (ESC) controller 304, an electrostatic chuck (ESC) sensor 306, an optical emission spectroscopy sensor (OES) 308, a heater power controller 310, and a power source 312, which may (or may not) be arranged as shown. In embodiments, the sensor and control system 300 may include fewer or greater sensors and controllers than shown in FIG. 3. The sensors and controllers in the sensor and control system 300 can be implemented in various positions and arrangements.

The optical temperature sensor 302 is a device used to measure temperature based on the interaction of light with a material whose optical properties change with temperature. Unlike traditional temperature sensors that might rely on electrical resistance (thermistors), thermocouples, or expansion of materials (bimetallic or gas thermometers), optical temperature sensors use light to determine temperature, which can offer several advantages, especially in challenging environments. The optical temperature sensor 302 can be, for example, a Fiber Bragg Grating (FBG) sensor, a fluorescence-based sensor, an optical pyrometer (radiation thermometer), an infrared thermometer, a Raman scattering sensor, or a thermographic camera. Using an optical temperature sensor 302 has numerous advantages, such as immunity to electromagnetic interference, intrinsic safety in explosive environments (since they do not generate sparks), high precision and sensitivity, and the possibility of remote sensing. These characteristics make them particularly suitable for plasma processing systems, where non-contact measurements are preferable.

In embodiments, the ESC controller 304 provides a precise voltage to the electrodes within the electrostatic chuck. This voltage creates the electrostatic force necessary to hold the wafer. The ESC controller 304 might need to manage both the clamping phase (when voltage is applied to hold the wafer) and the de-clamping phase (when the voltage is reduced or reversed to release the wafer). In embodiments, the ESC controller 304 manages heating or cooling circuits within the chuck to maintain the wafer at a specified temperature during processing. This temperature control is crucial for ensuring process uniformity and preventing thermal damage to the semiconductor devices. In embodiments, the ESC controller 304 is integrated into a plasma processing tool's overall process control system. In such embodiments, the ESC controller 304 receives input from and sends feedback to the central process control system to synchronize wafer handling with other process steps. In embodiments, the ESC controller 304 monitors various parameters of the electrostatic chuck, such as voltage levels, leakage currents, and in some cases, temperature. The ESC controller 304 can provide feedback to the system for diagnostics and process control purposes. In embodiments, the ESC controller 304 includes safety interlocks and diagnostic features to prevent damage to the wafer or the processing equipment in case of malfunctioning or out-of-spec operation.

The ESC sensor 306 is a device or component used to monitor or control an electrostatic chuck, such as the substrate holder 108 in the plasma processing system 100, during the fabrication of semiconductor devices. Maintaining the right temperature is critical for many semiconductor processes to ensure the correct reaction rates and material properties. In embodiments, the ESC sensor 306 measures the temperature of a chuck or wafer to ensure proper thermal management during processing. In embodiments, the ESC sensor 306 monitors the voltage applied to the electrostatic chuck to ensure that the wafer is held securely and that the clamping force is within the desired range. In embodiments, the ESC sensor 306 detects when the etching process has reached its endpoint by monitoring changes in certain parameters like RF (radio frequency) power, impedance, or even optical emissions. In embodiments, the ESC sensor 306 confirms the presence or absence of a wafer on the chuck, which is vital to prevent process errors or equipment damage. In embodiments, the ESC sensor 306, for chucks that use backside gas cooling, monitors the pressure of that gas to ensure proper cooling and control over wafer temperature.

OES sensor 308 is minimally invasive and can provide real-time results, making it ideal for plasma diagnostic applications. The strength of optical emission spectroscopy lies in its capability to conduct a non-disturbing characterization of plasma parameters. This involves mapping out atomic and molecular species through the emission from excited levels.

OES allows for a comprehensive survey of atomic and molecular species in plasma by scrutinizing the emission from excited states. By detecting and quantifying the specific wavelengths of light emitted, this spectroscopic method efficiently identifies various species within the plasma. Every species has a distinctive (i.e., unique fingerprint) atomic structure, level of excitation, and spectrum line, making it uniquely identifiable through OES. Operating on a non-perturbing setup, OES helps prevent changes in the plasma under study, thus ensuring the authenticity and reliability of the data obtained.

The mechanism of OES also helps identify excited species emitting in the Visible-Near Infrared (Vis-NIR) range. Different species, when excited, emit lights of varying frequencies. Those species that emit light in the visible light spectrum (i.e., from 380 to about 750 nanometers) to near-infrared light spectrum (i.e., from 750 to about 1000 nanometers) can be easily distinguished using OES.

In embodiments, OES sensor 308 is used to analyze the light emitted by plasma or other light-producing processes to determine the composition of the material being excited and to monitor the process parameters. OES sensor 308 can measure the light, either emitted or absorbed, by the plasma. The output data in the form of, for example, spectral lines contain information about the specific species present in the plasma, including their electronic state, temperature, and density.

During plasma etching, chemical vapor deposition (CVD), or physical vapor deposition (PVD), the plasma will emit light at various wavelengths. Each element in the plasma emits light at characteristic wavelengths when it is excited, known as its emission spectrum. By analyzing this light, the OES sensor 308 can identify the elements present in the plasma and often their relative abundances.

OES sensor 308 is particularly valuable in real-time process monitoring and control within plasma processing systems. In embodiments, the OES sensor 308 is used as an end-point detection device to identify when a particular layer has been fully etched by detecting changes in the intensity of specific spectral lines. In embodiments, the OES sensor 308 is used for process stability by monitoring the consistency of the plasma over time by observing the emission intensities of spectral lines. In embodiments, the OES sensor 308 is used for chamber condition by inferring the condition of the process chamber, such as the presence of contaminants or wear of components like electrodes, by observing unexpected spectral lines or changes in expected lines. In embodiments, the OES sensor 308 is used for process development to refine processes by providing immediate feedback on how changes in process conditions affect the plasma composition.

OES sensor 308 can be implemented using, for example, a spectrometer that disperses the light from the plasma onto a detector, which could be a photodiode array, charge-coupled device (CCD), or another type of optical sensor capable of detecting and quantifying light intensity at different wavelengths. The data is then processed to extract information about the process state or material being analyzed.

In embodiments, OES sensor 308 is embedded in a circular array within the focus ring 120 of the plasma processing system 100. Advantageously, this implementation will not alter the existing chamber form factor and will be economically viable by modifying existing parts. In embodiments, optical elements can be incorporated within a semi-transparent focus ring, which can assist in gathering sufficient light for efficient analysis.

A crucial factor to consider when obtaining OES is establishing an access window for the optical light to pass through. As the process involves the analysis of emitted light, it is important to provide an unobstructed path for this light to reach the spectroscopic instrument. This may often require the creation of an aperture or entry point for the incident light, ensuring that the light emissions have free access to the device. This aids in achieving precise and dependable data upon analysis, enhancing the overall effectiveness of the optical emission spectroscopy process.

The heater power controller 310 regulates the power supplied to heating elements to control the temperature of a system or process. The heater power controller 310 can modulate the power supplied to the heating element, and based on feedback from, for example, the optical temperature sensor 302, it can maintain and regulate a temperature within a desired range.

The power source 312 regulates the power supplied to the sensors and controllers of the sensor and control system 300. Power source 312 can be a dedicated electrical supply that ensures a stable and regulated power source to enable the accurate and reliable functioning of these components. Power source 312 can be used as a low-voltage power supply, an uninterruptible power supply (UPS), an isolator (to avoid noise or high-frequency interference), a power conditioner, or a power distribution unit for the sensors and controllers of the sensor, and control system 300.

Plasma processing systems operate under precise conditions where parameters are subject to change over time. These changes may be intentional (ramping up or down of power, for example) or due to system drift or shifts in equilibrium. In embodiments, the data collected from the sensors of the sensor and control system 300 are collected over different moments in time. For example, the OES sensor 308 captures data corresponding to the light intensity over a wavelength range (e.g., in the nanometer range) at distinct moments. Time-resolved data can help determine the uniformity and stability of a plasma over time. For example, variations in intensity at certain wavelengths may indicate fluctuations in the density or temperature of the plasma. By identifying and correcting for these variations, better uniformity and stability can be ensured across the processed substrate. Advantageously, this allows for the ability to closely monitor plasma processes and dynamically respond to changes, ensuring optimized operation, better quality control, and enhanced process knowledge-all crucial for advanced manufacturing and materials processing applications.

Further, plasma comprises various species, such as electrons, ions, radicals, and neutrals, at different excited states. The population of these species can change rapidly due to reactions occurring within the plasma. Time-resolved OES provides insight into the kinetics of these reactions by showing how the emission intensities of different species vary with time. This information is crucial for understanding reaction pathways and rates, which can be used to refine and optimize plasma processes.

Moreover, certain plasma behaviors might be transient and not easily detected without a time-resolved analysis. For instance, ignition sequences, instabilities, or short-lived species may only be present for milliseconds or microseconds. Continuous collection of OES data by the OES sensor 308 over distinct moments can reveal these ephemeral events, leading to a deeper understanding of the plasma physics at play or highlighting issues requiring attention within the plasma processing system 100.

Additionally, in some processes, such as plasma etching, it is important to know when to stop the process-known as end-point detection-to prevent over-etching or damage to the material. Time-resolved OES collected by OES sensor 308 can identify shifts in emission spectra that correspond to the completion of an etch process or other desired endpoint by detecting changes in the concentration of specific species or the overall plasma composition.

Inconsistent results or equipment malfunction can often be traced back through OES data captured over time by the OES sensor 308. If a problem arises during plasma processing, historical OES data can be analyzed to pinpoint when deviations occurred, aiding in diagnostics and troubleshooting.

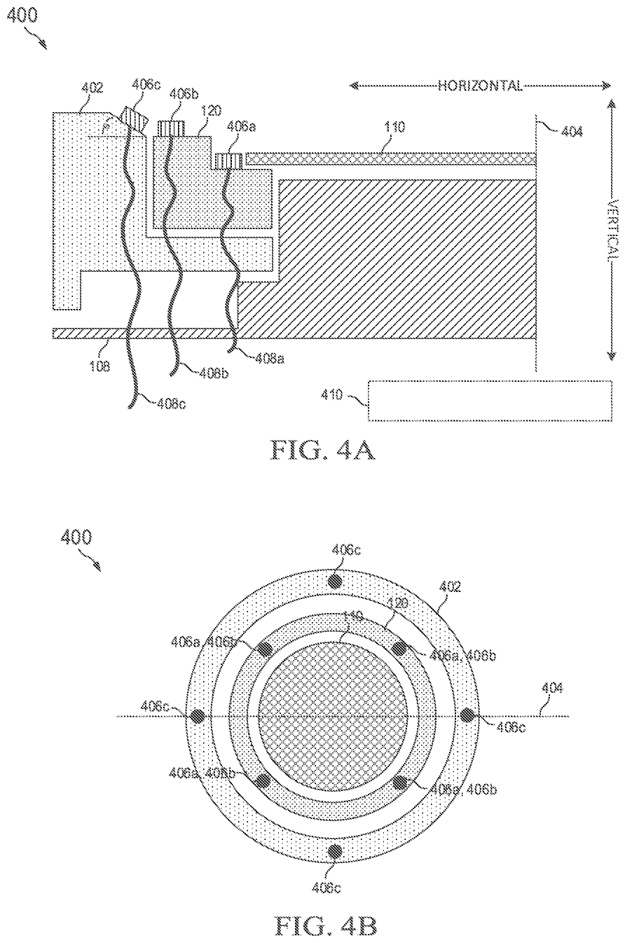

FIG. 4A illustrates a cross-sectional view of an embodiment ring assembly 400. FIG. 4B illustrates a top view of the ring assembly 400. The ring assembly 400 may be implemented in the plasma processing system 100. The ring assembly 400 includes the focus ring 120, the substrate holder 108, and a shadow ring 402, which may (or may not) be arranged as shown. Substrate 110 is placed on substrate holder 108 for plasma processing.

The cut-away view shown in FIG. 4A illustrates the ring assembly 400 from a centerline 404 to its outermost edge. As the cross-sectional view is symmetric across a central axis, for simplicity of discussion, one-half of the cross-section is shown. The other half, about the centerline 404, should be understood as an exact mirror image of the displayed side in FIG. 4A.

Focus ring 120 surrounds the substrate 110 (e.g., a silicon wafer). The primary function of the focus ring 120 is to affect the distribution of ions and electrons at the edge of the substrate 110. In many plasma systems, such as Reactive Ion Etching (RIE) or Plasma-Enhanced Chemical Vapor Deposition (PECVD), the edge of the substrate 110 might receive a different treatment than the center due to non-uniformities in the plasma. The focus ring 120 helps to focus or confine the plasma more uniformly over the surface of the substrate 110, minimizing these edge effects and contributing to a more consistent process across the whole wafer. By adjusting properties such as the placement, size, and material of the focus ring 120, process engineers can fine-tune the uniformity of the ion bombardment and chemical reactivity at the wafer's surface.

The shadow ring 402 is designed to protect the edge of substrate 110 from deposition during processes like PECVD or sputtering. During these deposition processes, unwanted accumulation of deposited material can occur at the wafer's edge, leading to irregularities and potentially impacting subsequent process steps or device performance. Shadow ring 402 creates a physical barrier that “shadows” the edge of the wafer, preventing or reducing deposition in that area. This helps ensure that only the desired area of the wafer receives the film or coating, thereby maintaining the quality and uniformity of the deposited layer.

In embodiments, the fiber optic cable 408a-c for the OES sensor 308 is embedded inside the ring assembly 400. The fiber optic cable 408a-c can be inserted via a bulkhead and mating connectors.

In embodiments, the fiber optic cable 408a-c is unterminated (i.e., bare) (not shown). In such embodiments, the endpoint of the fiber optic cable 408a-c is positioned to be at the surface of the focus ring 120, the shadow ring 402, or both. In embodiments, the bare end of the fiber optic cable 408a-c is pointed towards the substrate 110.

In embodiments, OES sensor 308 includes a fiber optic cable 408a-c coupled to an optical assembly 406a-c (as shown) defining the optical emission spectroscopy image plane. In embodiments, the optical assembly 406a-c includes a mirror, a focusing mirror, and a Bragg Mirror, or the like. In embodiments, the optical assembly 406a-c may be a collimation assembly or a light focusing assembly.

The optical assembly can define the image focal plane, which can range from 5 to 10 millimeters from the end of the fiber optic cable 408a-c. In embodiments, the optical assembly 406a-c is made from dielectric material. In embodiments, the optical assembly 406a-c has a longer focal length to allow increased levels of light collection. In embodiments, the optical assembly 406a-c is threaded to the fiber optic cable 408a-c at the end point of the fiber optic cable 408a-c.

In embodiments, the optical assembly 406a-c (or unterminated fiber optic cable 408a-c) is pointed toward the center or the edge of the substrate 110. In embodiments, the optical assembly 406a-c is angled with respect to a surface, such that the optical assembly 406a-c is pointed towards a specific location, such as the surface of the substrate 110. In such embodiments, mirrors can direct the collection point angle such that a specific volume is analyzed, similar to a prism or periscope. In embodiments, the optical assembly 406a-c is a gradient-index microoptical assembly (GRIN optical assembly or GRIN Rod optical assembly) with a radially varying index of refraction (e.g., from the center of the optical assembly to its periphery) that causes an optical ray to follow a sinusoidal propagation path through the optical assembly 406a-c.

In embodiments, the optical assembly 406a-c (or unterminated fiber optic cable 408a-c) scans a pencil-like volume (e.g., narrow and cylindrical volume) near the surface of the substrate 110. In embodiments, the optical assembly 406a-c scans a conical volume near the surface of the substrate 110. In embodiments, each optical assembly scans a volume at approximately (i.e., within 5%) between 0 millimeters and 6 millimeters from the surface of the substrate 110. This distance can be typically measured from the wafer surface to the edge of the volume being scanned.

In embodiments, using multiple optical assemblies 406a-c can provide a range of scan volumes at the surface of the substrate 110 that allows for a more focused detection mechanism that can advantageously improve the feedback, feedforward, and diagnostic processes.

In embodiments, each optical assembly 406a-c is telecentric, maintaining a constant magnification over a range of distances. This allows for improved measurement accuracy, reduced sensitivity to the positioning of the substrate 110, and uniformity in the sampling.

The fiber optic cable 408a-c can be easily inserted into the plasma chamber 106 at multiple points (as illustrated, for example, in FIGS. 4A-B) via a bulkhead (i.e., a mounting fixture that allows for the passage of the fiber optic cable 408a-c through a panel or enclosure), ensuring a secure and stable entry point for the fiber optic cable 408a-c. On the other side of the bulkhead, a mating connector can be used to join the fiber optic cable 408a-c to an optical assembly 406a-c. The connector ensures a precise and reliable optical interface. As systems may have varying requirements or physical configurations, the ability to insert fiber optics at several locations provides considerable flexibility in design and functionality.

The flexibility of the fiber optic cable 408a-c enables it to be routed in unique configurations, navigating tight bends and complex pathways within the physical structure of the plasma chamber 106 without significant loss of signal. Such adaptability can be crucial when setting up a spectroscopy system in confined spaces or integrating it within existing equipment where pathways for cables are limited.

The lightweight nature of the fiber optic cable 408a-c, especially those made entirely from plastic, including their ceramic ferrules (the rigid sleeve that encloses and aligns the fiber), makes them easy to handle and install without adding significant weight to the system. In embodiments, the fiber optic cable 408a-c is incorporated into components made of quartz and silicon, which are materials known to chip easily. Additionally, certain components within the process kits are designed with a thin profile. While a lightweight characteristic is not essential, it proves to be beneficial for the handling and installation of these elements in the process kits.

Regarding cost and availability, the fiber optic cable 408a-c is generally inexpensive and readily available commercially. This makes them an economically viable option for optical emission spectroscopy systems, lowering overall costs and easing procurement procedures.

The fiber optic cable 408a-c can be equipped with specialized connectors, such as right-angle connectors to the optical assembly 406a-c, which are useful for instances where space is constrained or where the cable needs to exit at an angle different from the path that the fiber optic cable 408a-c is fed through the mechanical structure.

In integrating the fiber optic cable 408a-c into an OES sensor 308, multiple solution paths are available for effectively channeling light from the sample being analyzed to the detection equipment, such as the optical assembly 406a-c. The design considerations for these paths often require balancing factors like optical efficiency, material compatibility, durability, and ease of integration.

In one embodiment, the fiber optic cable 408a-c is directly attached to a focus ring 120 made of silicon dioxide (SiO₂) or a silicon dioxide focus ring coated with silicon. Silicon dioxide, commonly called quartz or silica, is an excellent material for optical applications due to its high transparency across a broad range of wavelengths and resistance to high temperatures. In this configuration, the fiber optic cable 408a-c is directly affixed to a focus ring 120, positioned to collect and concentrate the light emitted from the plasma chamber 106 directly into the fiber optic cable 408a-c. This setup minimizes the number of optical interfaces, thereby reducing potential signal loss and improving signal transmission efficiency. Silicon coating can serve multiple purposes, such as protecting the underlying silicon dioxide from harsh environments or enhancing its light-collecting capabilities by altering its reflective properties. This coating could enable the focus ring 120 to increase durability if the system is used where silicon dioxide might be vulnerable to damage.

In embodiments, existing components can be modified to add space and enhance light gathering.

When using a focus ring 120 coated with f silicon, it may be advantageous to employ a light collecting element. Silicon is a reflective material, and as such, it may scatter some of the light away from the direct path toward the fiber optic cable 408a-c. By introducing a light-collecting element, such as the optical assembly or a mirror strategically placed within the system, it becomes possible to gather more scattered light and direct it into the fiber optic cable 408a-c for analysis. This element effectively maximizes the amount of light captured from the emission source, thus improving the accuracy and sensitivity of spectroscopic measurements.

In embodiments, the optical assembly 308a is arranged on the focus ring 120 and adjacent to the substrate 110. In embodiments, the optical assembly 308a is substantially (e.g., within 5%) on the same plane as the substrate 110, which is positioned on the substrate holder 108. In embodiments, the horizontal distance between optical assembly 308a and substrate 110 is between 0 and 20 millimeters; in one embodiment, it is at 16 millimeters.

In embodiments, the optical assembly 308b is arranged on the focus ring 120 and vertically positioned above the substrate 110. In embodiments, the vertical distance between the optical assembly 308b and the substrate 110 is between 0 and 4 millimeters, and in one embodiment, it is at 1 millimeter. In embodiments, the distance between the optical assembly 308b and the substrate 110 is between 0 and 60 millimeters, and in one embodiment, at 45 millimeters.

In yet another embodiment, the fiber optic cable 408c can be routed through the shadow ring 402, given its distinct position relative to the wafer edge. In embodiments, the shadow ring 402 is made of silicon dioxide. Shadow ring 402 can shield certain areas from direct illumination while allowing light to pass through or around in a controlled manner. By using silicon dioxide for the shadow ring 402, one can benefit from its optical transparency and thermal stability. Routing the fiber optic cable 408c through the shadow ring 402 can help manage stray light or shape the path of light to specific regions of interest within the spectroscopy apparatus. This approach may be particularly useful in complex systems where precise light management is needed to avoid interference and enhance detection accuracy.

The focus ring 120 is generally consumable part of the process, and its connection to anomalies occurring at the outer extremes of the wafer is well-established. Accordingly, the shadow ring 402 might be favored for its ability to indirectly indicate inconsistencies in the plasma at the wafer's edge. Moreover, the shadow ring 402 provides an expanded field of view for the OES fiber optic system compared to that offered by the focus ring 120. Further, by placing the optical assembly 308a at the shadow ring 402, monitoring of the plasma at the surface of the focus ring 120 can also be achieved, thereby yielding a better understanding of plasma nonuniformities at the wafer's perimeter.

In embodiments, the optical assembly 308c is arranged on the shadow ring 402 and vertically positioned above the substrate 110. In embodiments, as shown, the shadow ring 402 includes a bevel. In such embodiments, the optical assembly 308c is arranged on the bevel of the shadow ring 402 such that the optical assembly 308c is angled at θ degrees with respect to the horizontal plane. In embodiments, the angle θ between 0 and 30 degrees, and in one embodiment, it is 10 degrees. In embodiments, the vertical distance between the optical assembly 308c and the substrate 110 is between 0 and 8 millimeters, and in one embodiment, it is 2.5 millimeters. In embodiments, the distance between the optical assembly 308c and the substrate 110 is between 0 and 90 millimeters, and in one embodiment, it is 75 millimeters.

In an embodiment, the fiber optic cable 408a-c coupled to the optical assembly 406a-c is fed through insertion points within the focus ring 120, the shadow ring 402, the substrate holder 108, or a combination thereof. The other end (not coupled to the optical assembly 406a-c) of the fiber optic cable 408a-c can be fed to a computer or a processing system for data collection and analysis.

In embodiments, one or more optical assemblies 308a-c are arranged on the focus ring 120, the shadow ring 402, or both, as discussed above. In embodiments, the optical assembly 308a-c is arranged at equidistance alongside the focus ring 120, the shadow ring 402, or both to provide symmetrical remote sensing by the OES sensor 308 with respect to the plasma 112 generated in the plasma chamber 106.

As shown, four optical assemblies are placed at the focus ring 120 and the shadow ring 402 in FIG. 4B. It should be appreciated that the location and number of optical assemblies are non-limiting, and fewer or greater are similarly contemplated. Further, in embodiments, the optical assemblies are placed at any position (not limited to the positions shown in FIG. 4B) along the focus ring 120, the shadow ring 402, or both.

In embodiments, the optical assembly 308a-c is limited to being placed on the focus ring 120. In embodiments, the optical assembly 308a-c is limited to being placed on the shadow ring 402. In other embodiments, the optical assembly 308a-c is placed on the focus ring 120 and the shadow ring 402. It should be appreciated that the horizontal or vertical placement of the optical assembly 308a-c on the surface of the focus ring 120, the shadow ring 402, or both is not limited to that shown in FIGS. 4A-B. In other embodiments, the optical assembly 308a-c may be positioned at other horizontal or vertical arrangements.

In embodiments, other remote sensors, such as (but not limited to) the optical temperature sensor 302, are similarly placed at equidistance alongside the focus ring 120, the shadow ring 402, or both to provide symmetrical remote sensing.

In embodiments, given the flexibility of the fiber optic cable 408a-c, the routing of the fiber optic cable 408a-c may be through additional or fewer structural components from the optical assembly 308a-c to the analyzing processor. Thus, the illustration in FIG. 4A is non-limiting and provides an exemplary routing path for the fiber optic cable 408a-c within the plasma processing system 100.

In embodiments, an empty cavity 410 underneath the substrate holder 108 is used to route the fiber optic cable 408a-c for the ring assembly 400 or other sensors of the plasma processing system 100. The empty cavity 410 may allow extra fiber length or customized fiber connectors. In embodiments, the empty cavity 410 is greater than six inches in vertical dimensions.

In embodiments, the measurements from one or more optical assembly 308-c are fed through the fiber optic cable 408a-c to an application processor. In embodiments, the measurements are filtered using, for example, a filter optical assembly to collect a specific range of the light spectrum. The plasma characteristics collected by the optical assembly 308a-c are analyzed by the application processor and used for feedback, feedforward, or diagnostic purposes, for example.

In embodiments, a calibration step is added to the processing such that reflections of the light from the sidewalls 101, the base 107, and the top cover 105 are removed from the measurements.

It should be understood that the shapes drawn for the ring assembly 400 may differ from those shown in FIGS. 4A-B based on, for example, different processing applications. Thus, different shapes for the ring assembly are contemplated in other embodiments. The common feature for the different shapes of the ring assembly 400 is a focus ring 120 surrounding the substrate 110 and, optionally, a shadow ring 402 surrounding the focus ring 120.

It should be appreciated that in some embodiments, the ring assembly 400 may not

include a shadow ring 402 surrounding the focus ring 120. In such embodiments, the arrangement of the OES sensor 308 is limited to placements on the focus ring 120.

In embodiments, the focus ring 120 and the shadow ring 402 are replaceable parts of the ring assembly 400. For example, the focus ring 120 or the shadow ring 402 are exchanged for different sizes or shapes based on the processing application. As another example, the focus ring 120 or the shadow ring 402 can be consumable parts that degrade over time and will be replaced with identical or different mechanical structures.

A first aspect relates to a plasma chamber. The plasma chamber includes a substrate holder, a ring assembly, and a fiber optic cable. The substrate holder having a top surface and a bottom surface. The top surface of the substrate holder is configured to hold a substrate for plasma processing. The ring assembly includes a focus ring horizontally surrounding the substrate. The focus ring includes a cavity arranged in a vertical direction from the bottom surface of the substrate holder to the top surface of the substrate holder. The fiber optic cable is fed through the cavity. The fiber optic cable having an endpoint configured to collect light emitted by plasma to determine plasma species density as well as its atomic or ionic composition.

In a first implementation form of the plasma chamber according to the first aspect as such, the focus ring includes a plurality of cavities arranged in the vertical direction. A respective fiber optic cable is fed through each of the plurality of cavities. Each fiber optic cable having an associated endpoint configured to collect light emitted by the plasma.

In a second implementation form of the plasma chamber according to the first aspect as such or any preceding implementation form of the first aspect, the light emitted is in a visible range, a near-infrared range, or the visible range and the near-infrared range.

In a third implementation form of the plasma chamber according to the first aspect as such or any preceding implementation form of the first aspect, the endpoint is configured to collect light emitted at a surface or an edge of the substrate during plasma processing.

In a fourth implementation form of the plasma chamber according to the first aspect as such or any preceding implementation form of the first aspect, the plasma chamber further includes an optical assembly coupled to the endpoint. The optical assembly configured to provide an image focal plane defining a volume of light to be collected.

In a fifth implementation form of the plasma chamber according to the first aspect as such or any preceding implementation form of the first aspect, the ring assembly further includes a shadow ring horizontally surrounding the focus ring. The shadow ring having a second cavity arranged in the vertical direction. The plasma chamber further includes a second fiber optic cable fed through the second cavity. The second fiber optic cable having a second endpoint configured to collect light emitted by the plasma to determine its atomic or ionic composition.

In a sixth implementation form of the plasma chamber according to the first aspect as such or any preceding implementation form of the first aspect, the shadow ring has a bevel feature. The second endpoint of the second fiber optic cable is arranged at the bevel feature such that the second fiber optic cable collects the light emitted by the plasma at different angles with respect to the top surface of the substrate holder.

A second aspect relates to a plasma chamber. The plasma chamber includes a substrate holder, a ring assembly, and a fiber optic cable. The substrate holder having a top surface and a bottom surface. The top surface of the substrate holder configured to hold a substrate for plasma processing. The ring assembly having a focus ring horizontally surrounding the substrate and a shadow ring horizontally surrounding the focus ring. The shadow ring having a cavity. The fiber optic cable being fed through the cavity. The fiber optic cable having an endpoint configured to collect light emitted by plasma to determine its atomic or ionic composition.

In a first implementation form of the plasma chamber according to the second aspect as such, the shadow ring includes a plurality of cavities. A respective fiber optic cable is fed through each of the plurality of cavities. Each fiber optic cable having an associated endpoint configured to collect light emitted by the plasma.

In a second implementation form of the plasma chamber according to the second aspect as such or any preceding implementation form of the second aspect, the light emitted is in a visible range, a near-infrared range, or the visible range and the near-infrared range.

In a third implementation form of the plasma chamber according to the second aspect as such or any preceding implementation form of the second aspect, the endpoint is configured to collect light emitted at a surface or an edge of the substrate during plasma processing.

In a fourth implementation form of the plasma chamber according to the second aspect as such or any preceding implementation form of the second aspect, the plasma chamber further includes an optical assembly coupled to the endpoint, the optical assembly configured to provide an image focal plane defining a volume of light to be collected.

In a fifth implementation form of the plasma chamber according to the second aspect as such or any preceding implementation form of the second aspect, the shadow ring has a bevel feature. The endpoint is arranged at the bevel feature such that the fiber optic cable collects the light emitted by the plasma at different angles with respect to the top surface of the substrate holder.

In a sixth implementation form of the plasma chamber according to the second aspect as such or any preceding implementation form of the second aspect, the cavity is arranged vertically from the bottom surface of the substrate holder to the top surface of the substrate holder.

A third aspect relates to a ring structure for a plasma processing system. The ring structure including a focus ring and a shadow ring. The focus ring horizontally surrounding a substrate. The focus ring having a first cavity. A first fiber optic cable is fed through the first cavity to a first surface of the focus ring. The first fiber optic cable having an endpoint configured to collect light emitted by plasma at a first volume within a plasma chamber of the plasma processing system to determine its atomic or ionic composition. The shadow ring horizontally surrounds the focus ring. The shadow ring having a second cavity. A second fiber optic cable is fed through the second cavity to a first surface of the shadow ring. The second fiber optic cable having an endpoint configured to collect light emitted by plasma at a second volume within the plasma chamber to determine its atomic or ionic composition.

In a first implementation form of the ring structure according to the third aspect as such, the focus ring includes a plurality of cavities. A respective fiber optic cable is fed through each of the plurality of cavities. Each fiber optic cable having an associated endpoint configured to collect light emitted by plasma at different volumes within the plasma chamber.

In a second implementation form of the ring structure according to the third aspect as such or any preceding implementation form of the third aspect, the shadow ring includes a plurality of cavities. A respective fiber optic cable is fed through each of the plurality of cavities. Each fiber optic cable has an associated endpoint configured to collect light emitted by plasma at different volumes within the plasma chamber.

In a third implementation form of the ring structure according to the third aspect as such or any preceding implementation form of the third aspect, the light emitted is in a visible range, a near-infrared range, or the visible range and the near-infrared range.

In a fourth implementation form of the ring structure according to the third aspect as such or any preceding implementation form of the third aspect, the endpoint of the first optic cable, the second optical cable, or both, is configured to collect light emitted at a surface or an edge of the substrate during plasma processing.

In a fifth implementation form of the ring structure according to the third aspect as such or any preceding implementation form of the third aspect, the endpoint of the first optic cable, the second optical cable, or both, is coupled to an optical assembly. The optical assembly configured to provide an image focal plane defining a volume of light to be collected.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

The specification and drawings are, accordingly, to be regarded simply as an illustration of the disclosure as defined by the appended claims, and are contemplated to cover any and all modifications, variations, combinations, or equivalents that fall within the scope of the present disclosure.

What is claimed is:

1. A plasma chamber, comprising:
a substrate holder having a top surface and a bottom surface, the top surface of the substrate holder configured to hold a substrate for plasma processing;
a ring assembly comprising a focus ring horizontally surrounding the substrate, wherein the focus ring includes a cavity arranged in a vertical direction from the bottom surface of the substrate holder to the top surface of the substrate holder; and
a fiber optic cable fed through the cavity, the fiber optic cable having an endpoint configured to collect light emitted by plasma to determine its species density as well as atomic or ionic composition.

2. The plasma chamber of claim 1, wherein the focus ring includes a plurality of cavities arranged in the vertical direction, and wherein a respective fiber optic cable is fed through each of the plurality of cavities, each fiber optic cable having an associated endpoint configured to collect light emitted by the plasma.

3. The plasma chamber of claim 1, wherein the light emitted is in a visible range, a near-infrared range, or the visible range and the near-infrared range.

4. The plasma chamber of claim 1, wherein the endpoint is configured to collect light emitted at a surface or an edge of the substrate during plasma processing.

5. The plasma chamber of claim 1, further comprising an optical assembly coupled to the endpoint, the optical assembly configured to provide an image focal plane defining a volume of light to be collected.

6. The plasma chamber of claim 1, wherein the ring assembly further comprises a shadow ring horizontally surrounding the focus ring, the shadow ring having a second cavity arranged in the vertical direction, and wherein the plasma chamber further comprises a second fiber optic cable fed through the second cavity, the second fiber optic cable having a second endpoint configured to collect light emitted by the plasma to determine its species density as well as atomic or ionic composition.

7. The plasma chamber of claim 6, wherein the shadow ring has a bevel feature, and wherein the second endpoint of the second fiber optic cable is arranged at the bevel feature such that the second fiber optic cable collects the light emitted by the plasma at different angles with respect to the top surface of the substrate holder.

8. A plasma chamber, comprising:
a substrate holder having a top surface and a bottom surface, the top surface of the substrate holder configured to hold a substrate for plasma processing;
a ring assembly comprising a focus ring horizontally surrounding the substrate and a shadow ring horizontally surrounding the focus ring, wherein the shadow ring includes a cavity; and
a fiber optic cable fed through the cavity, the fiber optic cable having an endpoint configured to collect light emitted by plasma to determine its species density as well as atomic or ionic composition.

9. The plasma chamber of claim 8, wherein the shadow ring includes a plurality of cavities, and wherein a respective fiber optic cable is fed through each of the plurality of cavities, each fiber optic cable having an associated endpoint configured to collect light emitted by the plasma.

10. The plasma chamber of claim 8, wherein the light emitted is in a visible range, a near-infrared range, or the visible range and the near-infrared range.

11. The plasma chamber of claim 8, wherein the endpoint is configured to collect light emitted at a surface or an edge of the substrate during plasma processing.

12. The plasma chamber of claim 8, further comprising an optical assembly coupled to the endpoint, the optical assembly configured to provide an image focal plane defining a volume of light to be collected.

13. The plasma chamber of claim 8, wherein the shadow ring has a bevel feature, and wherein the endpoint is arranged at the bevel feature such that the fiber optic cable collects the light emitted by the plasma at different angles with respect to the top surface of the substrate holder.

14. The plasma chamber of claim 8, wherein the cavity is arranged vertically from the bottom surface of the substrate holder to the top surface of the substrate holder.

15. A ring structure for a plasma processing system, the ring structure comprising:
a focus ring horizontally surrounding a substrate, wherein the focus ring includes a first cavity, wherein a first fiber optic cable is fed through the first cavity to a first surface of the focus ring, the first fiber optic cable having an endpoint configured to collect light emitted by plasma at a first volume within a plasma chamber of the plasma processing system to determine its atomic or ionic composition; and
a shadow ring horizontally surrounding the focus ring, wherein the shadow ring includes a second cavity, wherein a second fiber optic cable is fed through the second cavity to a first surface of the shadow ring, the second fiber optic cable having an endpoint configured to collect light emitted by plasma at a second volume within the plasma chamber to determine its species density as well as atomic or ionic composition.

16. The ring structure of claim 15, wherein the focus ring includes a plurality of cavities, and wherein a respective fiber optic cable is fed through each of the plurality of cavities, each fiber optic cable having an associated endpoint configured to collect light emitted by plasma at different volumes within the plasma chamber.

17. The ring structure of claim 15, wherein the shadow ring includes a plurality of cavities, and wherein a respective fiber optic cable is fed through each of the plurality of cavities, each fiber optic cable having an associated endpoint configured to collect light emitted by plasma at different volumes within the plasma chamber.

18. The ring structure of claim 15, wherein the light emitted is in a visible range, a near-infrared range, or the visible range and the near-infrared range.

19. The ring structure of claim 15, wherein the endpoint of the first optic cable, the second optical cable, or both, is configured to collect light emitted at a surface or an edge of the substrate during plasma processing.

20. The ring structure of claim 15, wherein the endpoint of the first optic cable, the second optical cable, or both, is coupled to an optical assembly, the optical assembly configured to provide an image focal plane defining a volume of light to be collected.
